(19) United States
(12) Patent Application Publication
(10) Pub. No.: US 2012/0241852 A1
(43) Pub. Date: Sep. 27, 2012

(54) SEMICONDUCTOR DEVICE AND METHOD FOR MANUFACTURING SAME

(76) Inventor: Toshiyuki SASAKI, Kanagawa-ken (JP)

(21) Appl. No.: 13/234,683

(22) Filed: Sep. 16, 2011

(30) Foreign Application Priority Data
Mar. 25, 2011 (JP) 2011-068929

(51) Int. Cl. H01L 29/78; H01L 21/28

(52) U.S. Cl. 257/331; 257/288; 438/571; 257/E29.255; 257/E29.262; 257/E21.158; 257/E21.19

(57) ABSTRACT

According to one embodiment, a semiconductor device includes a semiconductor substrate, plural stacked bodies, an insulating side wall, an interlayer insulating layer, and a contact. Plural stacked bodies are provided on the semiconductor substrate so as to extend in parallel to one another. Each of the plural stacked bodies includes a gate insulating layer, a gate electrode, and an insulating layer. The insulating side wall covers a side face of the gate electrode in an upper end part thereof and does not cover the side face of the gate electrode in a part thereof contacting the gate insulating layer. The interlayer insulating layer is provided on the semiconductor substrate and covers the stacked bodies. The contact is provided in the interlayer insulating layer between the stacked bodies and is connected to the semiconductor substrate.

### CROSS-REFERENCE TO RELATED APPLICATIONS

This application is based upon and claims the benefit of priority from the prior Japanese Patent Application No. 2011-068929, filed on Mar. 25, 2011; the entire contents of which are incorporated herein by reference.

### FIELD

Embodiments described herein relate generally to a semiconductor device and a method for manufacturing the same.

### BACKGROUND

Recently, along with the miniaturization of the semiconductor device, a process using self-alignment is used frequently.

The self-alignment in the manufacturing method of a semiconductor device means that an already formed pattern is utilized as a mask for the next process and the next process is carried out without mask alignment.

An example includes formation of a source-drain region by ion-implantation through the use of a gate electrode as a mask. In this case, it is possible to determine the position of a gate electrode and the position of the source-drain region without lithographic restrictions.

In the case of a self-aligned contact (SAC) hole, a resist pattern opening for processing a contact hole is not only formed on a contact part but also can be spread to a hard mask region formed on the gate electrode. Then, a hard mask on the gate electrode works as an etching stopper together with the resist pattern and a desired contact hole is formed between the neighboring gate electrodes. Furthermore, at this time, the opening of the resist pattern may not always have a hole shape but may be an opening extending in a line. Also in this case, the hard mask on the gate electrode works as an etching stopper and a contact hole is formed between the neighboring gate electrodes. Therefore, it is possible to reduce the degree of lithographic difficulty of forming the resist pattern.

### BRIEF DESCRIPTION OF THE DRAWINGS

FIG. 1 is a perspective view illustrating a semiconductor device according to a first embodiment;

FIG. 2 is a cross-sectional view illustrating the semiconductor device according to the first embodiment and a cross-sectional view along the plane A-A′ shown in FIG. 1;

FIG. 3 is a perspective view illustrating a semiconductor device according to a second embodiment;

FIG. 4 is a cross-sectional view illustrating the semiconductor device according to the second embodiment and a cross-sectional view along the A-A′ plane shown in FIG. 3;

FIG. 5 is a perspective view illustrating a semiconductor device according to a third embodiment;

FIG. 6 is a cross-sectional view illustrating the semiconductor device according to the third embodiment and a cross-sectional view along the A-A′ plane shown in FIG. 5;

FIG. 7 is a process cross-sectional view illustrating a manufacturing method according to a fourth embodiment;

FIG. 8 is a process cross-sectional view illustrating the manufacturing method according to the fourth embodiment;

FIG. 9 is a process cross-sectional view illustrating the manufacturing method according to the fourth embodiment;

FIG. 10 is a process cross-sectional view illustrating the manufacturing method according to the fourth embodiment;

FIG. 11 is a process cross-sectional view illustrating the manufacturing method according to the fourth embodiment;

FIG. 12 is a process plan view illustrating the manufacturing method according to the fourth embodiment;

FIG. 13 is a process cross-sectional view along the A-A′ line shown in FIG. 12;

FIG. 14 is a process cross-sectional view along the B-B′ line shown in FIG. 12;

FIG. 15 is a process cross-sectional view along the C-C′ line shown in FIG. 12;

FIG. 16 is a process cross-sectional view illustrating the manufacturing method of the semiconductor device according to the fourth embodiment;

FIG. 17 is a process cross-sectional view illustrating the manufacturing method of the semiconductor device according to the fourth embodiment;

FIG. 18 is a process cross-sectional view illustrating the manufacturing method of the semiconductor device according to the fourth embodiment;

FIG. 19 is a process cross-sectional view illustrating the manufacturing method of the semiconductor device according to the fourth embodiment;

FIG. 20 is a process cross-sectional view illustrating the manufacturing method of the semiconductor device according to the fourth embodiment;

FIG. 21 is a process cross-sectional view illustrating the manufacturing method of the semiconductor device according to the fourth embodiment;

FIG. 22 is a process cross-sectional view illustrating the manufacturing method of the semiconductor device according to the fourth embodiment;

FIG. 23 is a process cross-sectional view illustrating the manufacturing method of the semiconductor device according to the fourth embodiment;

FIG. 24 is a process cross-sectional view illustrating the manufacturing method of the semiconductor device according to the fourth embodiment;

FIG. 25 is a cross-sectional view illustrating an upper part of the gate electrode of the semiconductor device according to the fourth embodiment;

FIG. 26 is a process cross-sectional view illustrating a manufacturing method of a semiconductor device according to a comparative example of the fourth embodiment;

FIG. 27 is a process cross-sectional view illustrating the manufacturing method of the semiconductor device according to the comparative example of the fourth embodiment;

FIGS. 28A and 28B are cross-sectional views illustrating an upper part of a gate electrode of the semiconductor device according to the comparative example of the fourth embodiment;

FIG. 29 is a process cross-sectional view illustrating a manufacturing method of a semiconductor device according to a fifth embodiment;

FIG. 30 is a process cross-sectional view illustrating the manufacturing method of the semiconductor device according to the fifth embodiment;

FIG. 31 is a process cross-sectional view illustrating the manufacturing method of the semiconductor device according to the fifth embodiment;

FIG. 32 is a process cross-sectional view illustrating the manufacturing method of the semiconductor device according to the fifth embodiment;

FIG. 33 is a process cross-sectional view illustrating the manufacturing method of the semiconductor device according to the fifth embodiment;

FIG. 34 is a process cross-sectional view illustrating the manufacturing method of the semiconductor device according to the fifth embodiment;

FIG. 35 is a process cross-sectional view illustrating the manufacturing method of the semiconductor device according to the fifth embodiment;

FIG. 36 is a process cross-sectional view illustrating the manufacturing method of the semiconductor device according to the fifth embodiment;

FIG. 37 is a process cross-sectional view illustrating the manufacturing method of the semiconductor device according to the fifth embodiment;

FIG. 38 is a process cross-sectional view illustrating the manufacturing method of the semiconductor device according to the fifth embodiment;

FIGS. 39A and 39B are process cross-sectional views illustrating a manufacturing method of a semiconductor device according to a sixth embodiment, and 39A is a process cross-sectional view along the B-B′ line shown in 39B and 39B is a process cross-sectional view along the A-A′ line shown in 39A, in each of the drawings;

FIGS. 40A and 40B are process cross-sectional views illustrating the manufacturing method of the semiconductor device according to the sixth embodiment, and 40A is a process cross-sectional view along the B-B′ line shown in 40B and 40B is a process cross-sectional view along the A-A′ line shown in 40A, in each of the drawings;

FIGS. 41A and 41B are process cross-sectional views illustrating the manufacturing method of the semiconductor device according to the sixth embodiment, and 41A is a process cross-sectional view along the B-B′ line shown in 41B and 41B is a process cross-sectional view along the A-A′ line shown in 41A, in each of the drawings;

FIGS. 42A and 42B are process cross-sectional views illustrating the manufacturing method of the semiconductor device according to the sixth embodiment, and 42A is a process cross-sectional view along the B-B′ line shown in 42B and 42B is a process cross-sectional view along the A-A′ line shown in 42A, in each of the drawings;

FIGS. 43A and 43B are process cross-sectional views illustrating the manufacturing method of the semiconductor device according to the sixth embodiment, and 43A is a process cross-sectional view along the B-B′ line shown in 43B and 43B is a process cross-sectional view along the A-A′ line shown in 43A, in each of the drawings; and

FIGS. 44A and 44B are process cross-sectional views illustrating the manufacturing method of the semiconductor device according to the sixth embodiment, and 44A is a process cross-sectional view along the B-B′ line shown in 44B and 44B is a process cross-sectional view along the A-A′ line shown in 44A, in each of the drawings.

### DETAILED DESCRIPTION

In general, according to one embodiment, a semiconductor device includes a semiconductor substrate, plural stacked bodies, an insulating side wall, an interlayer insulating layer, and a contact. Plural stacked bodies are provided on the semiconductor substrate so as to extend in parallel to one another. Each of the plural stacked bodies includes a gate insulating layer, a gate electrode, and an insulating layer. The gate insulating layer is provided on the semiconductor substrate. The gate electrode is provided on the gate insulating layer. The insulating layer is provided on the gate electrode. The insulating side wall covers a side face of the gate electrode in an upper end part thereof and does not cover the side face of the gate electrode in a part thereof contacting the gate insulating layer. The interlayer insulating layer is provided on the semiconductor substrate and covers the stacked bodies. The contact is provided in the interlayer insulating layer between the stacked bodies and is connected to the semiconductor substrate.

According to another embodiment, a method is disclosed for manufacturing a semiconductor device. The method can form an insulating layer on a semiconductor substrate. The method can form a conductive film on the insulating layer. The method can form plural hard masks on the conductive film. The plural hard masks have an insulating property and extend in parallel to one another. The method can stack the insulating layer, the conductive film, and the hard mask to thereby form plural stacked bodies which extend in parallel to one another, by etching the conductive film and the insulating layer through the use of the hard mask as a mask. The method can embed sacrificial material in a part which is located in a lower part of a space between the stacked bodies and includes at least a space between the insulating layers, but does not include a space between the hard masks. The method can form an insulating side wall on a side face of the stacked bodies on the sacrificial material. The method can remove the sacrificial material. The method can form an interlayer insulating layer on the semiconductor substrate. The interlayer insulating layer covers the stacked bodies. The method can form a through-hole in the interlayer insulating layer. The through-hole reaches the semiconductor substrate. The method can embed conductive material in the through-hole and form a contact.

Various embodiments will be described hereinafter with reference to the accompanying drawings.

### First Embodiment

Embodiments of the invention will now be described with reference to the drawings.

First, a first embodiment will be described.

The embodiment is an embodiment of a semiconductor device.

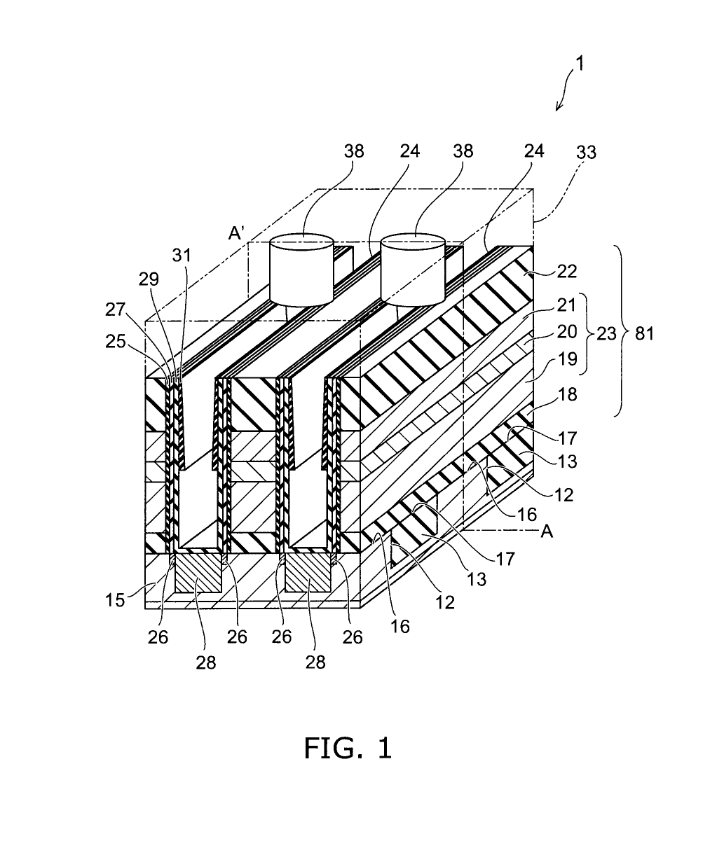

FIG. 1 is a perspective view illustrating a semiconductor device according to the first embodiment.

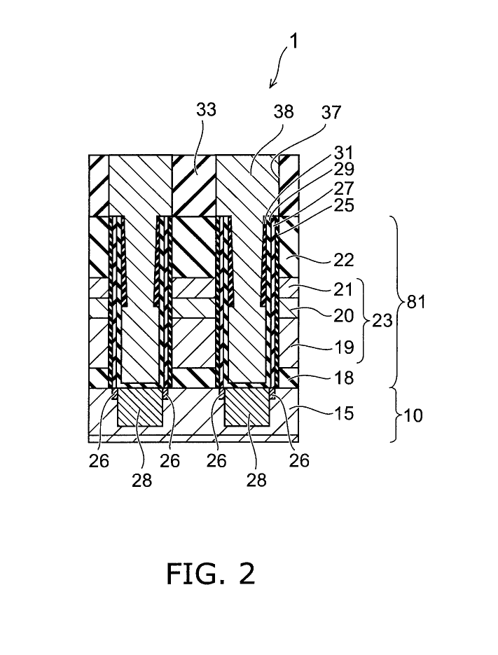

FIG. 2 is a cross-sectional view illustrating the semiconductor device according to the first embodiment and a cross-sectional view along the plane A-A′ shown in FIG. 1.

First, a configuration of the semiconductor device 1 according to the first embodiment will be described.

As shown in FIGS. 1 and 2, the semiconductor device 1 is provided with a semiconductor substrate, for example, a silicon substrate 10. On the upper face of the silicon substrate 10, plural trenches 12 extending in one direction are formed in parallel to one another. Insulating material, for example, silicon oxide 13 is embedded inside the trenches 12. The region within the trench 12 where the silicon oxide 13 is embedded is defined as a shallow trench isolation (STI) region 17. The region sandwiched by the STI regions 17 is defined as an active region 16.

An impurity, for example, boron is introduced in the silicon substrate 10 from the upper face of the silicon substrate 10 down to a region deeper than the bottom of the trench 12 and a well 15 is formed.

Plural stacked bodies 81 extending in parallel to one another are provided on the silicon substrate 10. The stacked bodies 81 extend in a direction perpendicular to the trenches 12. Trenches 24 are provided between the neighboring stacked bodies 81 in a direction in which the stacked bodies 81 extend on the upper face of the silicon substrate 10.

A silicon oxide film 18, for example, is provided in the bottom part of the stacked bodies 81 as a gate insulating layer. A gate electrode 23 is provided on the silicon oxide film 18. The structure of the gate electrode 23 is a multilayer film structure. That is, the gate electrode 23 is configured with a poly-silicon film 19, a barrier metal film 20, a low-resistance metal film 21, in order from the bottom to the top. The poly-silicon film 19 is formed by poly-silicon in which an impurity such as phosphorus, for example, has been introduced. The barrier metal film 20 can include a tungsten nitride film. The low-resistance metal film 21 can include a tungsten film. A hard mask 22 is provided on the low-resistance metal film 21. A material of the hard mask 22 can include silicon nitride.

An extended region 26 in which an impurity, for example, phosphorus has been introduced, is formed in the upper layer part of the silicon substrate 10 on both sides of a region directly below the gate electrode 23. A source-drain region 28 is formed in a region between the respective regions directly below the gate electrodes 23 in the upper layer part of the silicon substrate 10, and between the extended regions 26. An impurity, for example, phosphorus is introduced in the source-drain region 28 in a concentration higher than that introduced in the extended region 26. Furthermore, the impurity, for example, phosphorus is introduced in the source-drain region 28 more deeply than in the extended region 26. A silicide layer, for example, a nickel silicide layer (not shown in the drawing) is formed in the surface layer of the source-drain region 28.

An extension side wall 25 is provided on a side face of the stacked bodies 81. A source-drain side wall 27 is provided on a side face of the extension side wall 25. The position of a side face edge part of the extension side wall 25 when viewed from above is approximately the same as the position of the edge part of the extended region 26 on the gate electrode 23 side when viewed from above. The position of an edge part of the source-drain side wall 27 when viewed from above is approximately the same as the position of the edge part of the source-drain region 28 on the gate electrode 23 side when viewed from above.

A stopper film 29 is provided on a side face of the source-drain side wall 27 and on the silicon substrate 10 in the part located between the respective regions directly below the gate electrodes 23. That is, the stopper film 29 can be said to be provided on the inner surface of the trench 24. The stopper film 29 is removed in the part on the source drain region 28.

Insulating side walls 31 are provided on both of the side faces of the gate electrode 23 in the upper part thereof. The upper end of the insulating side wall 31 coincides with the upper face of the hard mask 22. The lower end of the insulating side wall 31 is located on a side face of the barrier metal film 20 in the gate electrode 23.

Accordingly, the upper end part side face of the gate electrode 23 is covered by the insulating side wall 31. On the other hand, the side face of the gate electrode 23 in the part thereof contacting the gate insulating layer is not covered by the insulating side wall 31.

An interlayer insulating layer 33 is provided on the silicon substrate 10. The interlayer insulating layer 33 is omitted in FIG. 1 for easy viewing. A contact hole 37 is formed in the interlayer insulating layer 33 on the source-drain region 28. A contact 38 is provided inside the contact hole 37. The contact 38 is bonded to the silicide layer on the surface of the source-drain region 28.

The three silicon nitride films of the extension side wall 25, the source-drain side wall 27, and the stopper film are formed between the side face of the gate electrode 23 in the part thereof contacting the gate insulating layer and the contact 38. In contrast, the four silicon nitride films of the above three silicon nitride films and the additional insulating side wall 31 are formed on the side face of the gate electrode 23 in the upper end part thereof. Furthermore, the gate electrode 23 is formed into a pillar bodies having the same width at the top and the bottom thereof. Accordingly, the contact 38 is formed so as to have a larger width in the part thereof close to the silicon substrate 10 where the contact 38 is not sandwiched by the insulation side walls 31 than in the part thereof where the contact 38 is sandwiched by the insulating side walls 31.

The contact hole 37 in the interlayer insulating layer 33 is formed so as to be spread to the hard mask region formed on the gate electrode 23 by an opening of the self-aligned contact hole 37. Therefore, the part of the contact 38 in the interlayer insulating layer 33 is formed to so as have a larger width than the part thereof sandwiched by the insulating side walls 31.

Next, action of the semiconductor device according to the first embodiment will be described.

First, a voltage is applied to the gate electrode 23 of the semiconductor device 1. Then, the silicon oxide film 18 provided between the gate electrode 23 and the silicon substrate 10 works as a gate insulating layer. The part of the silicon substrate 10 covered by the silicon oxide film 18 works as a channel and an inversion layer is formed. Then, when a voltage is applied between the source-drain region 28, carriers move in the inversion layer and current flows. By the change of the voltage applied to the gate electrode 23, the amount of current flowing between the source-drain region 28 is controlled.

Next, an advantage of the semiconductor device according to the first embodiment will be described.

In the embodiment, the insulating side wall 31 is provided on the upper side face of the stacked bodies 81 and thus short circuit between the gate electrode 23 and the contact 38 is prevented securely. In contrast, the insulating side wall 31 is not provided on the lower part of the stacked bodies 81, that is, on the side face of the gate electrode 23 in the part thereof contacting the gate insulating layer. Therefore, an area for bonding the upper face of the source-drain region 28 and the contact 38 is not narrowed. As a result, interface resistance is not increased. Accordingly, even when a width between the electrodes is reduced with the progress in miniaturization, it is possible to securely prevent the short circuit with the gate electrodes 23 and to form the self-aligned contact 38 while securing conductivity with the source-drain region 28. As a result, it is possible to realize high integration of the semiconductor device 1.

### Second Embodiment

Next, a second embodiment will be described.

The embodiment relates to a semiconductor device of a recess type transistor.

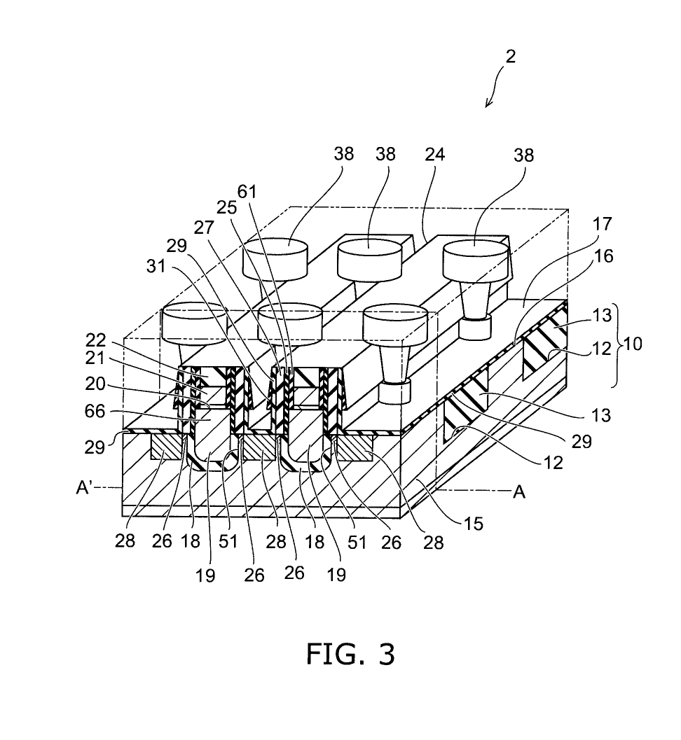

FIG. 3 is a perspective view illustrating a semiconductor device according to the second embodiment.

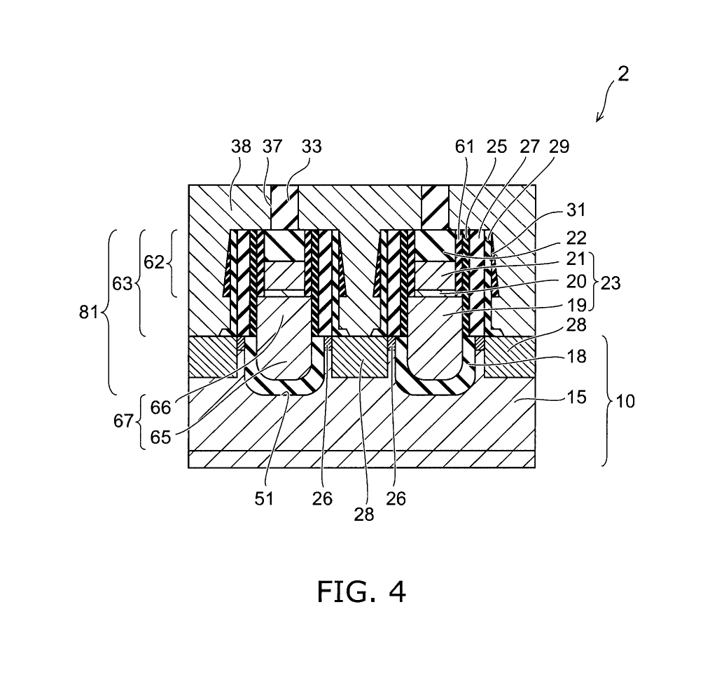

FIG. 4 is a cross-sectional view illustrating the semiconductor device according to the second embodiment and a cross-sectional view along the A-A′ plane shown in FIG. 3.

First, a configuration of the semiconductor device according to the second embodiment will be described.

As shown in FIGS. 3 and 4, in the semiconductor device 2 according to the embodiment, a silicon substrate 10 is provided with a trench 51 in a direction perpendicular to an extension direction of an STI region 17 and an active region 16.

A silicon oxide film 18, for example, is provided on the inner surface of the trench 51 as a gate insulating layer. Furthermore, conductive material, for example, poly-silicon is embedded inside the trench 51. The part of the poly-silicon embedded inside the trench 51 is referred to as a lower conduction part 65. An impurity, for example, phosphorus is introduced in the poly-silicon.

An extended region 26 in which an impurity, for example, phosphorus has been introduced is formed in a region in the surface layer part of the active region 16 including the outer edge of the trench 51. Source-drain regions 28 are formed next to the extended regions 26 on both of the sides sandwiching the trench in the surface layer part of the active region 16, respectively.

Furthermore, a pillar body made up of a conductive material is provided on the trench 51 along the trench 51 having a width approximately the same as that of the trench 51. This pillar body provided on the trench 51 is made up of poly-silicon which is the same material as the conductive material embedded inside the trench 51, and is integrated with the lower conduction part 65 which is embedded in the trench 51. The poly-silicon pillar body provided on the trench 51 is referred to as an upper conduction part 66. The upper conduction part 66 and the lower conduction part 65 are altogether referred to as a conduction part 67.

A barrier metal film 20 is provided on the upper conduction part 66. The barrier metal film 20A can include a stacked layer of titanium and titanium nitride, and a titanium nitride film. A low-resistance metal film 21 is provided on the barrier metal film 20. A hard mask 22 is provided on the low-resistance metal film 21. A gate electrode 23 is formed of the conduction part 67, the barrier metal film 20, and the low-resistance metal film 21.

The hard mask 22, the low-resistance metal film 21, and the barrier metal film 20 are stacked to thereby compose a pillar body 62. When the barrier metal film 20 in the pillar body 62 is the stacked layer of titanium and titanium nitride, the titanium included in the stacked layer is sometimes oxidized by oxidization heat treatment in a manufacturing process. Accordingly, for preventing the oxidation of the titanium, a barrier metal side wall 61 is provided on a side face of the stacked bodies made up of the hard mask 22, the low-resistance metal film 21, and the barrier metal film 20. A material of the barrier metal side wall 61 can include silicon nitride. When the barrier metal side wall 61 is provided, the stacked structure including the barrier metal side wall 61 is referred to as the pillar body 62.

The upper conduction part 66 and the pillar body 62 compose a pillar body 63. Furthermore, the stacked layer including the pillar body 63, the lower conduction part 65, and the silicon oxide film 18 is referred to as a stacked body 81.

Between the neighboring pillar bodies 63A, trench 24 is provided in the extension direction of the pillar body 63 on the silicon substrate 10.

On a side face of the pillar body 63 in the stacked body 81, an extension side wall 25 and a source-drain side wall 27 are provided.

A stopper film 29 is provided on a side face of the source-drain side wall 27 and a part of the silicon substrate 10 located between respective regions directly below the pillar bodies 63.

An insulating side wall 31 is provided on both of the upper part side faces of the pillar body 63 in the stacked bodies 81. Also in the embodiment, the upper end part side face of the gate electrode 23 is covered by the insulating side wall 31. In contrast, the side face of the gate electrode 23 in the part thereof contacting the gate insulating layer is not covered by the insulating side wall 31. Accordingly, the part of a contact 38 which is not sandwiched by the insulating side walls 31 has a larger width than the part thereof sandwiched by the insulating side walls 31.

The configuration of the embodiment except the above is the same as that of the above described first embodiment, and thus explanation will be omitted.

Next, the operation of the semiconductor device according to the second embodiment will be described.

First, a voltage is applied to the gate electrode 23 of the semiconductor device 2. Then, the silicon oxide film 18 provided on the inner surface of the trench 51 works as a gate insulating layer. The region of the silicon substrate 10 along the trench 51 works as a channel and an inversion layer is formed.

The operation of the embodiment except the above is the same as that of the above described first embodiment, and thus explanation will be omitted.

Next, an advantage of the semiconductor device according to the second embodiment will be described.

Also in the embodiment, the insulating side wall 31 is not formed on the side face of the gate electrode 23 corresponding to the bottom part of the trench 24. Therefore, an area for bonding the upper face of the source-drain region 28 and the contact 38 is not narrowed. As a result, the interface resistance is not increased.

Furthermore, a transistor having a recess structure can be manufactured and a channel length can be increased while the width of the gate electrode 23 is miniaturized. Moreover, the edges of the source-drain region 28 are extended and current flowing in the channel can be increased.

The advantage of the embodiment except the above is the same as that of the above described first embodiment, and thus explanation will be omitted.

### Third Embodiment

Next, a third embodiment will be described.

The embodiment is a semiconductor device of a fin-type transistor.

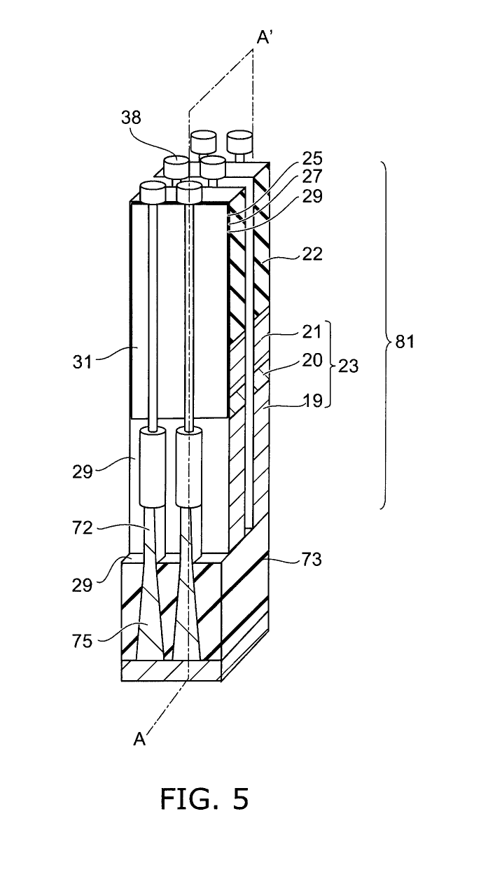

FIG. 5 is a perspective view illustrating a semiconductor device according to the third embodiment.

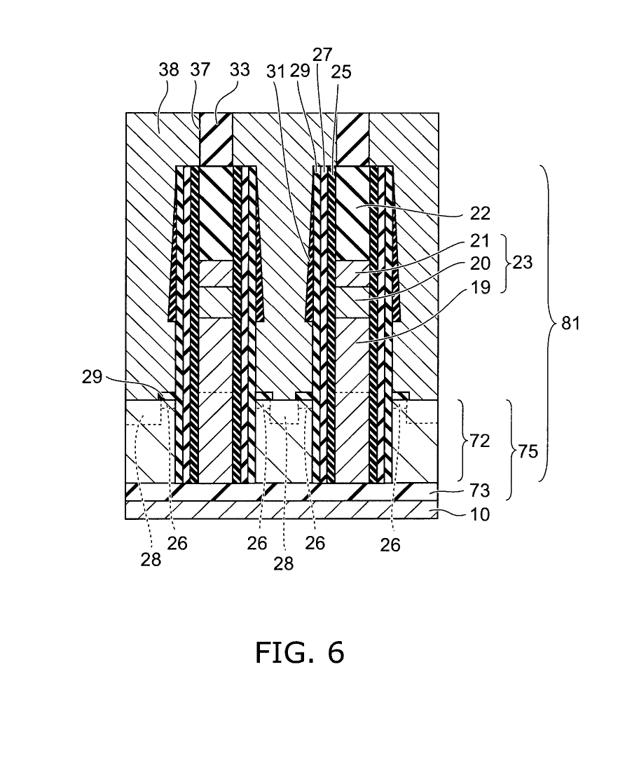

FIG. 6 is a cross-sectional view illustrating the semiconductor device according to the third embodiment and a cross-sectional view along the A-A′ plane shown in FIG. 5.

First, a configuration of the semiconductor device according to the embodiment will be described.

As shown in FIGS. 5 and 6, the semiconductor device 3 is provided with a semiconductor substrate, for example, a silicon substrate 10.

On the upper face of the silicon substrate 10, plural pillar bodies 75 formed so as to extend in one direction are formed in parallel to one another. The pillar bodies 75 are integrated with the silicon substrate 10 and each of the pillar bodies 75 has a shape protruding from the silicon substrate 10. The width of the lower part of the pillar body 75 is configured to be larger than the width of the upper part. Between the pillar body 75 and the pillar body 75, a silicon oxide film 73 having a height lower than the protrusion of the pillar body 75 is formed. The region where the silicon oxide film 73 is formed is referred to as an STI region 74 and the part of the pillar body 75 on the silicon oxide film 73 is referred to as a fin 72. Accordingly, the fin 72 is also formed on the upper face of the silicon substrate 10 so as to extend in one direction.

A gate electrode 23 is provided on the silicon substrate 10 including the fin 72 so as to extend in a direction perpendicular to the extension direction of the fin 72. Between the neighboring gate electrodes 23A, trench 24 is provided in the direction in which the gate electrode 23 extends on the upper face of the silicon substrate 10. The length of the trench 24 in the width direction is referred to as a “width”. As a gate insulating layer, a silicon oxide film 18, for example, is provided on the surfaces of the gate electrode 23 facing the upper face and the side faces of the fin 72.

The gate electrode 23 is configured to have a multilayer film structure. Films composing the multilayer film structure are configured to be a poly-silicon film 19, a barrier metal film 20, and a low-resistance metal film 21 in order from the bottom to the top. A hard mask 22 is provided on the low-resistance metal layer 21. The stacked layer including the hard mask 22, the gate electrode 23, and the silicon oxide film 18 is referred to as a stacked bodies 81.

Extended regions 26 are formed, in the upper layer part of the upper face and the side faces of the fin 72, on both sides of a region directly below the gate electrode 23. A source-drain region 28 is formed, in the upper layer part of the upper face and the side faces of the fin 72 and in a region between the respective regions directly below the gate electrodes 23 and between the extended regions 26.

An extension side wall 25 is provided on a side face of the stacked bodies 81 so as to cross over the fin 72. A source-drain side wall 27 is provided on a side face of the extension side wall 25 so as to cross over the fin 72.

A stopper film 29 is provided on a side face of the source-drain side wall 27 and on a part of the fin 72 located between the respective regions directly below the gate electrodes 23.

An insulating side wall 31 is provided on both of the side faces of the stacked body 81 in the upper part thereof. Also in the third embodiment, the upper end part side face of the gate electrode 23 is covered by the insulating side wall 31. In contrast, the side wall of the gate electrode 23 in the part thereof contacting the gate insulating layer is not covered by the insulating side wall 31. Accordingly, the part of the contact 38 which is not sandwiched by the insulating side walls 31 has a larger width than the part thereof which is sandwiched by the insulating side walls 31.

The configuration of the embodiment except the above is the same as those in the above described first and second embodiments, and thus explanation will be omitted.

Next, the operation of the semiconductor device according to the third embodiment will be described.

First, a voltage is applied to the gate electrode 23 of the semiconductor device 3. Then, the silicon oxide film 18 provided on the upper face and the side faces of the fin 72 works as a gate insulating layer. The region of the fin 72 covered by the silicon oxide film 18 works as a channel and an inversion layer is formed.

The operation of the embodiment except the above is the same as those of the above described first and second embodiments, and thus explanation will be omitted.

Next, an advantage of the semiconductor device according to the third embodiment will be described.

Also in the embodiment, the insulating side wall 31 is not formed on the side face of the gate electrode 23 corresponding to the bottom part of the trench 24. Therefore, an area for bonding the upper face of the source-drain region 28 and the contact 38 is not narrowed. As a result, the interface resistance is not increased.

Furthermore, a transistor having a fin structure can be manufactured and a channel area contacting the gate electrode 23 can be increased to thereby increase current flowing in the channel, while the width of the gate electrode 23 is miniaturized.

The advantage of the embodiment except the above is the same as those of the above described first and second embodiments.

### Fourth Embodiment

Next, a fourth embodiment will be described.

The embodiment is a manufacturing method of the semiconductor device according to the first embodiment.

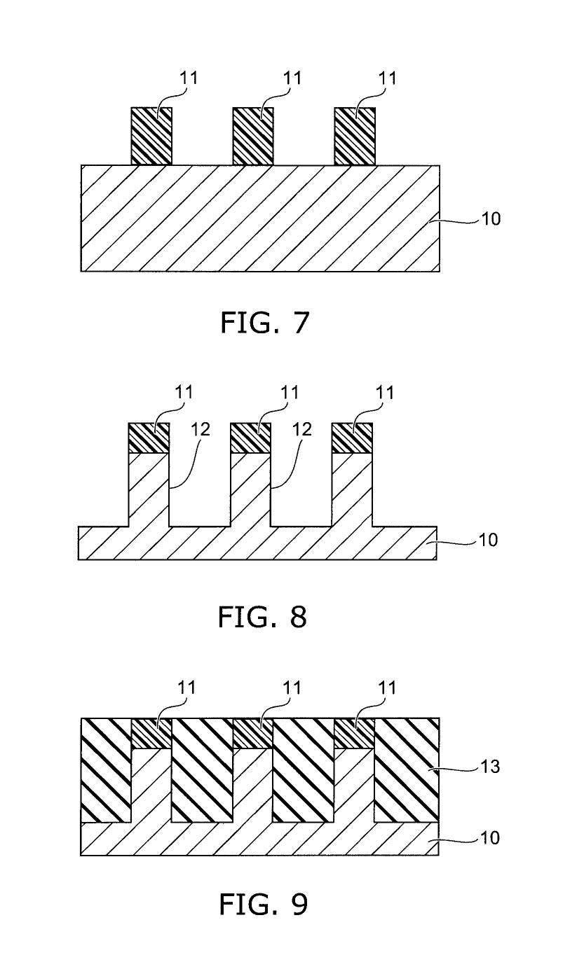

FIGS. 7 to 11 are process cross-sectional views illustrating the manufacturing method according to the fourth embodiment,

FIG. 12 is a process plan view illustrating the manufacturing method according to the fourth embodiment,

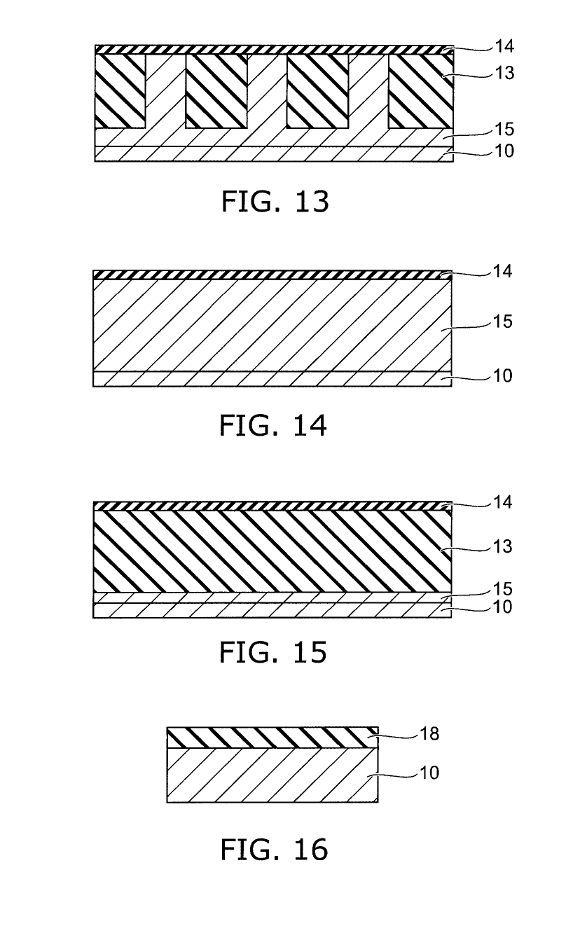

FIG. 13 is a process cross-sectional view along the A-A′ line shown in FIG. 12,

FIG. 14 is a process cross-sectional view along the B-B′ line shown in FIG. 12,

FIG. 15 is a process cross-sectional view along the C-C′ line shown in FIG. 12,

FIG. 16 to FIG. 24 are process cross-sectional views illustrating the manufacturing method of the semiconductor device according to the fourth embodiment, and

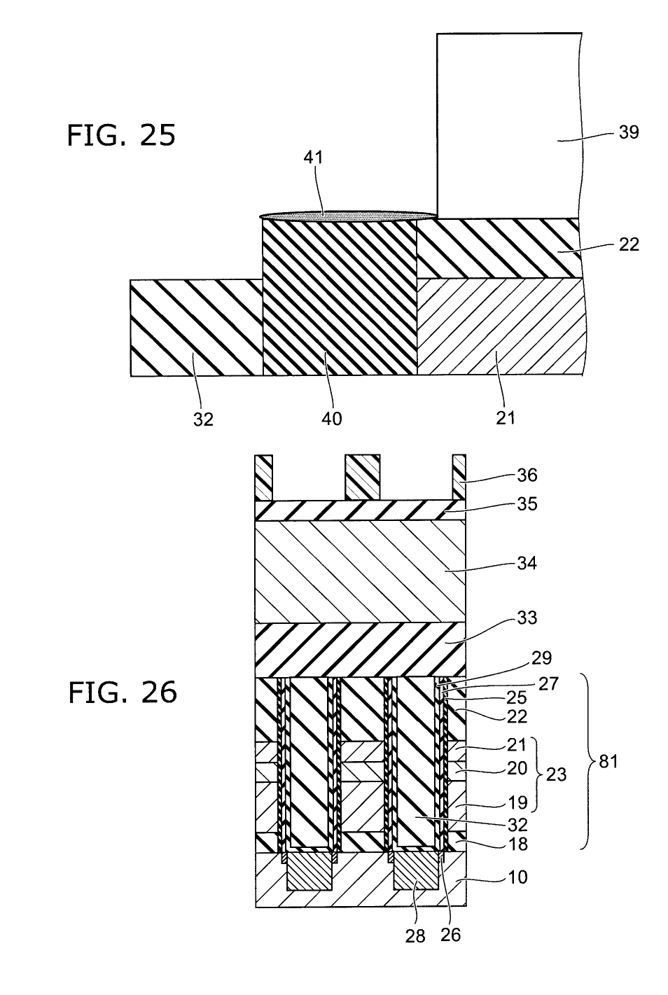

FIG. 25 is a cross-sectional view illustrating an upper part of the gate electrode of the semiconductor device according to the fourth embodiment.

First, as shown in FIG. 7, a silicon substrate 10 made up of single crystal silicon (Si), for example, is prepared. After that, a silicon nitride film, for example, is formed, as a film serving as the hard mask 11, on the silicon substrate 10, and then the hard mask 11 is formed by patterning through the use of a photolithography method or the like. The hard masks 11 are formed in parallel to one another in one direction on the silicon substrate 10.

Then, as shown in FIG. 8, reactive ion etching is carried out through the use of the hard mask 11 as a mask and the trench 12 serving as the STI region 17 is formed in the upper layer part of the silicon substrate 10. At this time, the region which is covered by the hard mask 11 so as not to be etched becomes the active region 16.

After that, as shown in FIG. 9, the upper face of the silicon substrate 10 including the trench 12 and the hard mask 11 is covered by a silicon oxide film 13. Then, the silicon oxide film 13 is polished by a CMP (Chemical Mechanical Polishing) method until the surface of the hard mask appears and the upper face of the silicon oxide film 13 is flattened.

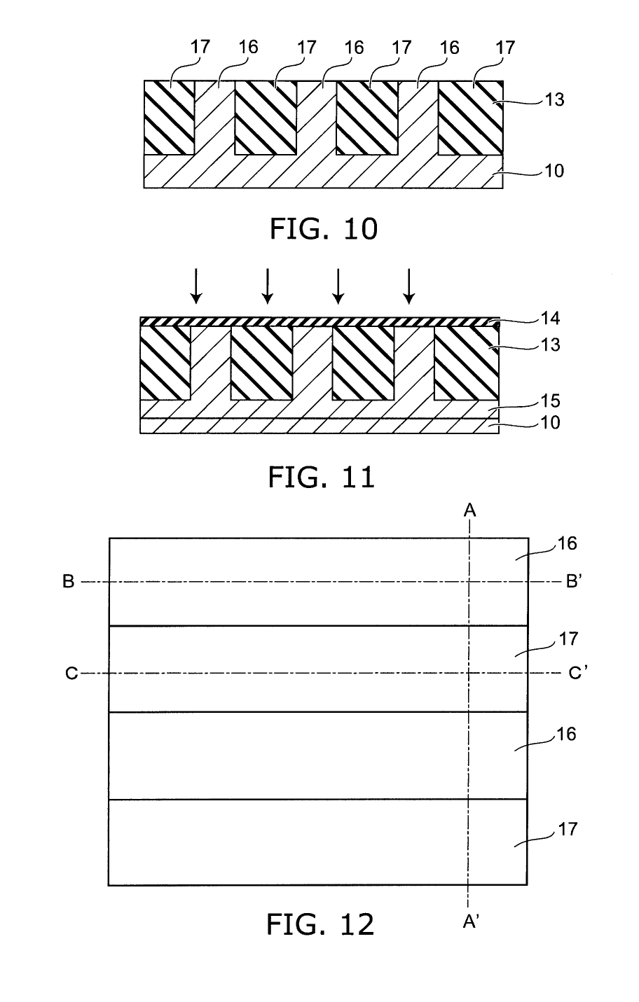

Next, as shown in FIG. 10, the silicon oxide film 13 is removed by wet etching down to the lower face of the hard mask 11 (refer to FIG. 9), that is, down to the upper face of the part of the silicon substrate 10 covered by the hard mask 11. After that, the hard mask 11 is removed by wet etching. The region of the silicon substrate 10 where the upper face thereof appears is the active region 16. Furthermore, the region where the silicon oxide film 13 is embedded in the trench 12 is the STI region 17. The upper face of the silicon oxide film 13 appears on the surface of the STI region 17.

Then, as shown FIG. 11, a silicon oxide film 14 is formed on the upper face of the silicon substrate 10 including the active region 16 and the STI region 17. After that, boron, for example, is introduced as an impurity by an ion implantation method from the upper face of the silicon oxide film 14. The depth of the introduction is set to be from the surface of the silicon substrate 10 down to a region deeper than the bottom part of the trench 12. Therefore, in the active region 16, the boron is introduced in the silicon substrate 10 from the upper face of the silicon substrate 10 down to the depth corresponding to the region deeper than the bottom part of the trench 12. In the STI region 17, the boron is introduced in the silicon substrate 10 from the bottom face of the trench 12 down to a region deeper than the bottom face of the trench 12. The region where the boron is introduced in the silicon substrate 10 becomes the p-type well 15.

As shown in FIGS. 12 to 15, the STI regions 17 extending in one direction in parallel to one another are formed on the silicon substrate 10 by the above described process. Then, the active region 16 is formed so as to be disposed between the STI regions 17.

The silicon oxide film 14 is omitted from the drawing in FIG. 12 while being formed on the surface of the silicon substrate 10.

Next, as shown in FIG. 16, the silicon oxide film 14 on the silicon substrate 10 (refer to FIGS. 13 to 15) is removed and a silicon oxide film 18, for example, is formed on the upper face of the silicon substrate 10 as the gate insulating layer.

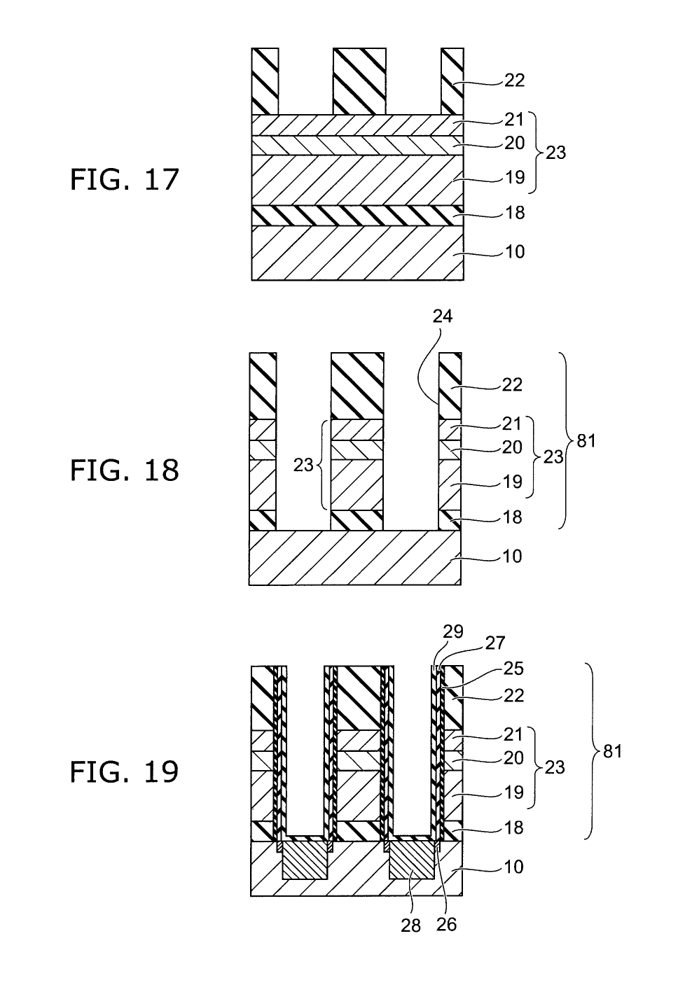

After that, as shown in FIG. 17, a poly-silicon film 19 serving as a part of the gate electrode 23 is formed on the upper face of the silicon oxide film 18. Next, a tungsten nitride film (WN), for example, is formed on the upper face of the poly-silicon film 19 as the barrier metal film 20. Then, a tungsten film (W), for example, is formed thereon as the low-resistance metal film 21. In the embodiment, the gate electrode 23 includes the poly-silicon film 19, the barrier metal film 20, and the low-resistance metal film 21.

The hard mask 22 is formed on the low-resistance metal film 21. A silicon nitride film, for example, is formed on the low-resistance metal film 21 and then the hard mask 22 is formed by patterning through the use of the lithography method. The hard mask 22 is set as plural strip-shaped parts extending in a direction perpendicular to the extension direction of the STI region 17.

Next, as shown in FIG. 18, reactive ion etching is carried out through the use of the hard mask 22 as a mask and the low-resistance metal film 21, the barrier metal film 20, the poly-silicon film 19, and the gate insulating layer 18 are removed selectively. Therefore, the stacked bodies 81 stacking the gate insulating layer 18, the poly-silicon film 19, the barrier metal film 20, the low-resistance metal film 21, and the hard mask 22 is formed. The gate electrode 23 is formed of the low-resistance metal film 21, the barrier metal film 20, and the poly-silicon film 19 in the stacked bodies 81. Meanwhile, the silicon substrate 10 appears on the surface of the part thereof which is not covered by the hard mask 22.

The stacked bodies 81 is formed as a pillar body extending in a direction perpendicular to the extension direction of the STI region 17. The trench 24 is formed between the neighboring gate electrodes 23. That is, the formed trench 24 divides the gate electrode 23. The trench 24 extends in the same direction as the extension direction of the gate electrode 23.

Next, as shown in FIG. 19, the extension side wall 25 is formed on the side face of the stacked bodies 81. A silicon nitride film is formed on the silicon substrate 10 and then the part except the side face of the stacked bodies 81 is removed to thereby form the extension side wall 25. Then, phosphorus is ion-implanted in the silicon substrate 10 through the use of the stacked bodies 81 and the extension side wall 25 as a mask. Therefore, the extended region 26 is formed on the silicon substrate 10 in the region which is not covered by the stacked bodies 81 or the extension side wall 25.

Furthermore, the source-drain side wall 27 is formed on the side face of the stacked bodies 81. Then, phosphorus is ion-implanted in the silicon substrate 10 through the use of the stacked bodies 81, the extension side wall 25, and the source-drain side wall 27 as a mask. Therefore, the source-drain region 28 is formed on the silicon substrate 10 in the region which is not covered by the stacked bodies 81, the extension side wall 25, and the source-drain side wall 27.

The phosphorus is implanted in the source-drain region 28 in a higher concentration than that of the implantation in the extended region 26. Furthermore, the phosphorus is implanted in the source-drain region 28 more deeply than in the extended region 26.

After that, nickel is deposited and then the surface of the source-drain region 28 is made to become silicide by heat treatment. Next, unreacted nickel is removed.

Then, the stopper film 29 is formed on the side face of the source-drain side wall 27 and on the part of the silicon substrate 10 located between respective regions directly below the stacked bodies 81. A silicon nitride film is formed on the silicon substrate 10 and then removed in the part except the side face of the source-drain side wall 27 and the part of the silicon substrate 10 located between the respective regions directly below the stacked bodies 81 to thereby form the stopper film 29. Therefore, the three silicon nitride films of the extension side wall 25, the source-drain side wall 27, and the stopper film 29 are formed on the side face of the stacked bodies 81.

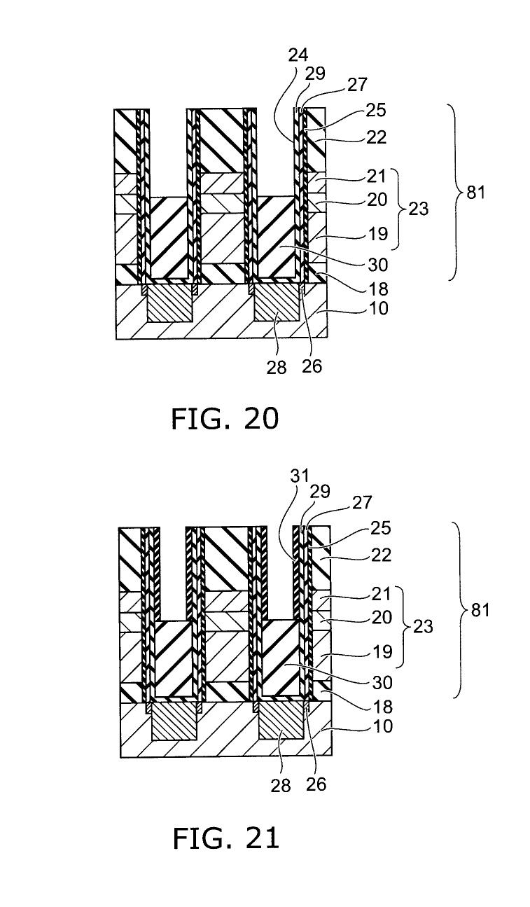

Next, as shown in FIG. 20, sacrificial material 30 is embedded in the inside bottom part of the trench 24. The sacrificial material 30 can include a material containing carbon.

The method of embedding the material including carbon in the trench 24 can include an embedding method using a CVD method or the like. First, the material containing carbon, hydrogen, and nitrogen is deposited to thereby form a film on the silicon substrate 10. Even a film having a carbon content of approximately 100% can be formed. The material containing carbon, hydrogen, and nitrogen is embedded in a part between the gate electrodes 23, that is, in the lower part of the trench 24 at least including a space between the hard masks 22. Next, the part except the inside bottom part of the trench 24 is removed to thereby form the sacrificial material 30. The upper face of the sacrificial material 30 is set to be located lower than a position where the low-resistance metal film 21 of the gate electrode 23 is formed. The method of embedding the sacrificial material 30 can include a sputter method or a spin-coating method other than the CVD method. The sputter method embeds the material including carbon in the trench 24 by sputtering through the use of a target of a material including carbon. The spin-coating method coats the material including carbon on the silicon substrate 10 to thereby embed the material including carbon in the trench 24. After the embedding, the part except the inside bottom part of the trench 24 is removed to thereby form the sacrificial material 30 in the same way as in the CVD method.

Next, as shown in FIG. 21, the insulating side wall 31 is formed on the side face of the stacked bodies 81. A silicon nitride film is formed on the silicon substrate 10 by a CVD method or the like and then the part except the side face of the stacked bodies 81 by an RIE method is removed to thereby form the insulating side wall 31. The upper end of the insulating side wall 31 coincides with the upper face of the stacked bodies 81. The lower end of the insulating side wall 31 coincides with the upper face of the sacrificial material 30. Since the upper face of the sacrificial material 30 is set to be located lower than the position where the low-resistance metal film 21 of the gate electrode 23 is formed, the lower end of the insulating side wall 31 is also located lower than the position where the low-resistance metal film 21 of the gate electrode 23 is formed. Accordingly, the upper end side face of the gate electrode 23 is covered by the insulating side wall 31 and the side face of the gate electrode 23 in the part thereof contacting the gate insulating layer is not covered by the insulating side wall 31.

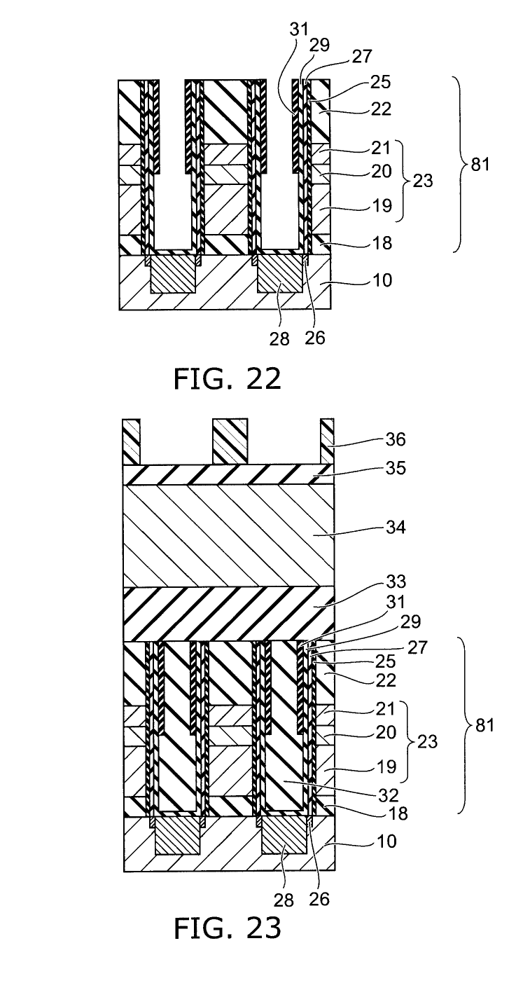

After that, as shown in FIG. 22, the sacrificial material 30 is removed by an ashing method. Therefore, the four silicon nitride films of the extension side wall 25, the source-drain side wall 27, the stopper film 29, and the insulating side wall 31 are formed on the respective side faces of the hard mask 22 and the low-resistance metal film 21 of the stacked bodies 81.

In contrast, the three silicon nitride films of the extension side wall 25, the source-drain side wall 27, and the stopper film 29 are formed on the side face of the stacked bodies 81 which has been covered by the sacrificial material 30. These silicon nitride films are not integrated in the manufacturing process of the semiconductor device 1 and can be discriminated also after the semiconductor device 1 has been manufactured.

Next, as shown in FIG. 23, a silicon oxide film 32 such as polysilazane, for example, is embedded inside the trench 24, and the silicon oxide film 32 is polished by the CMP method until the surface of the hard mask 22 and respective ends of the extension side wall 25, the source-drain side wall 27, the stopper film 29, and the insulating side wall 31 appear, and the upper face of the silicon oxide film 32 is flattened. Then, a silicon oxide film is deposited as the interlayer insulating layer 33 and an organic film 34, a silicon oxide film 35, and a resist 36 are formed thereon as a multilayer resist film.

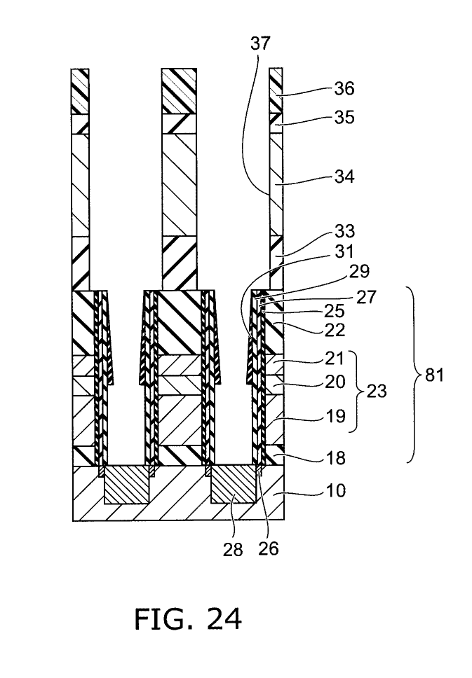

Next, as shown in FIG. 24, the patterning of the contact hole 37 is carried out. An opening region of the resist 36 in the self-aligned contact hole 37 is not only spread to a region corresponding to the bonding part of the upper face of the source-drain region 28 with the contact 38, but also spread to a region corresponding to the hard mask 22 of the gate electrode 23. At this time, the resist 36 and the hard mask 22 becomes an etching stopper. Then, an RIE method is applied through the use of the resist 36 as a mask, and the silicon oxide film 35, the organic film 34, the interlayer insulating layer 33, and the silicon oxide film 32 are removed selectively. In this manner, the contact hole 37 reaching the source-drain region 28 is formed between the gate electrodes 23.

Sometimes, the patterning shape of the resist 36 in the self-aligned contact hoe 37 is a line shape along the trench 24 other than a hole shape. Also in such a case, the hard mask 25 of the gate electrode 23 functions as a stopper and the contact hole 37 is formed between the gate electrodes 23.

After that, conductive materials, for example, barrier metal such as titanium and metal material such as tungsten are embedded in the contact hole 37, and the contact 38 is formed.

In this manner, as shown in FIGS. 1 and 2, the semiconductor device 1 is manufactured.

Next, an advantage of the embodiment will be described.

As shown in FIG. 25, in the embodiment, a silicon nitride film 40 including the four silicon nitride films of the extension side wall 25, the source-drain side wall 27, the stopper film 29, and the insulating side wall 31 is formed on the respective side faces of the hard mask 22 and the low-resistance metal film 21. While the four silicon nitride films are not discriminated in FIG. 25, these silicon nitride films are not integrated in the manufacturing process of the semiconductor device 1 and can be discriminated also after the semiconductor device 1 has been manufactured.

Accordingly, the respective upper faces of the hard mask 22 and the silicon nitride film 40 are exposed widely in the formation process of the self-aligned contact hole 37. At the time of the etching for forming the contact hole 37, in the silicon oxide film 32 inside the trench 24, oxygen is supplied from the silicon oxide film 32, and thus carbon included in etching gas is removed, and etching product 41 is not deposited on the silicon oxide film 32. In contrast, the hard mask 22 and the silicon nitride film 40 do not include oxygen in the respective films, and thus the carbon is not removed and the etching product 41 is deposited thereon.

Since the insulating side wall 31 is formed and the upper faces of the hard mask 22 and the silicon nitride film 40 are opened by the patterning of the resist 36 to thereby have a large area, the etching gas is easily supplied on the respective upper faces of the hard mask 22 and the silicon nitride film 40 and the thick etching product 41 is deposited on the hard mask 22 and the silicon nitride film 40 and functions as an etching stopper. Accordingly, the etching proceeds in the case of the silicon oxide film 32 but the etching does not proceed in the case of the hard mask 22 and the silicon nitride film 40, and thus the electrical contact between the low-resistance metal film 21 of the gate electrode 23 and the contact 38 never occurs.

Meanwhile, the insulating side wall 31 is not formed on the side face of the gate electrode 23 corresponding to the bottom part of the trench 24. Accordingly, the area for bonding the upper face of the source-drain region 28 with the contact 38 is not narrowed. As a result, the interface resistance is not increased.

Furthermore, when a material including carbon is used as the sacrificial material 30, the sacrificial material 30 can be etched without causing the hard mask 22, the extension side wall 25, and the source-drain side wall 27, which are made up of silicon nitride, and the STI region 17 and the gate insulating layer, which are made up of silicon oxide, to be etched.

Accordingly, according to the embodiment, the self-aligned contact hole can be formed even when the width of the electrode is narrowed with the progress of miniaturization, and thus it is possible to manufacture a highly integrated semiconductor device.

### Comparative Example of the Fourth Embodiment

Next a comparative example of the fourth embodiment will be described.

The comparative example is a manufacturing method of a semiconductor device in the case of not forming the insulating side wall 31.

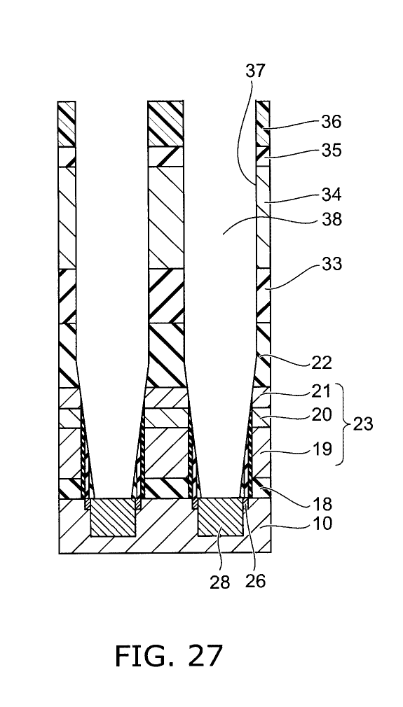

FIGS. 26 and 27 are process cross-sectional views illustrating the manufacturing method of a semiconductor device according to the comparative example of the fourth embodiment.

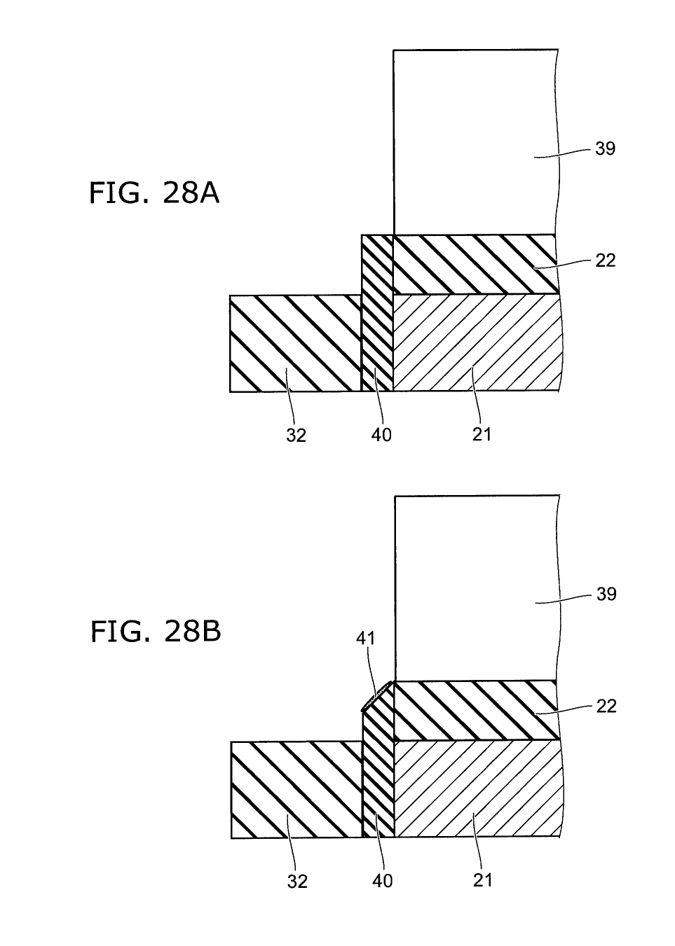

FIGS. 28A and 28B are cross-sectional views illustrating an upper part of a gate electrode of the semiconductor device according to the comparative example of the fourth embodiment.

The processes shown in FIGS. 7 to 19 in the fourth embodiment are the same as those in the comparative example, and thus explanation will be omitted.

As shown in FIG. 26, in the comparative example, the insulating side wall 31 is not formed and the silicon oxide film 32, the interlayer insulating layer 33, the organic film 34, the silicon oxide film 35, and the resist 36 are formed.

After that, as shown in FIG. 27, the contact hole 37 is formed and the contact 38 is formed in the contact hole 37.

In the comparative example, as shown in FIG. 27, the electrical contact between the low-resistance metal film 21 of the gate electrode 23 and the contact 38 occurs.

As shown in FIGS. 28A and 28B, in the comparative example, the insulating side wall 31 is not formed. The silicon nitride film 40 does not include the insulating side wall 31. Accordingly, in the formation process of the self-aligned contact hole 37, the area exposed on the respective upper faces of the hard mask 22 and the silicon nitride film 40 is smaller than that in the case of the fourth embodiment. Therefore, it is difficult to supply the etching gas and deposit the etching product 41, which becomes the etching stopper, on the respective upper faces of the hard mask 22 and the silicon nitride film 40. Furthermore, as shown in FIG. 28B, ion incidence is not perfectly perpendicular in the corner portion etching of a corner portion and thus the corner portion is formed into a slanted shape and is more easily etched than a flat part. Accordingly, the hard mask 22 and the silicon nitride film 40 are etched in the comparative example.

Therefore, the electrical contact between the low-resistance metal film 21 of the gate electrode 23 and the contact 38 comes to occur.

### Fifth Embodiment

Next, a fifth embodiment will be described.

The embodiment is an embodiment of a manufacturing method for the semiconductor device according to the second embodiment.

Hereinafter, the embodiment will be described with reference to the drawings.

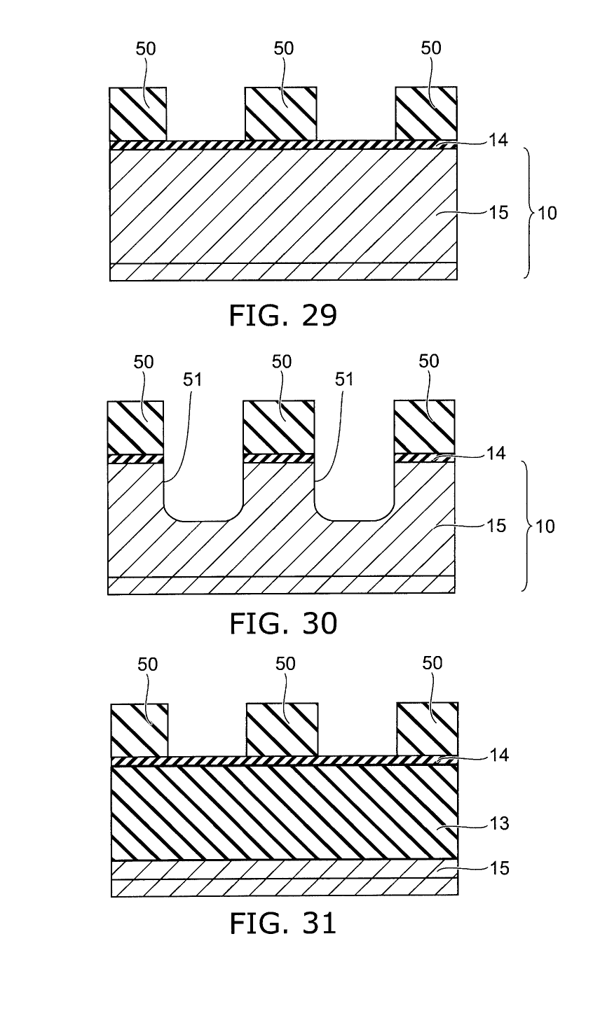

FIGS. 29 to 38 are process cross-sectional views illustrating a manufacturing method of a semiconductor device according to the fifth embodiment.

First, the processes shown in FIGS. 7 to 15 are carried out as in the above described fourth embodiment. Explanation about these processes will be omitted.

Next, as shown in FIG. 29, in a cross section corresponding to the cross section along the B-B′ line of FIG. 12, a silicon nitride film, for example, is formed on the silicon substrate 10 as a film serving as a hard mask 50 and then the hard mask 50 is formed by patterning using the photolithography method or the like. The hard mask 50 extends in a direction perpendicular to a trench 12 for forming the STI region 17.

Next, as shown in FIG. 30, reactive ion etching is carried out through the use of the hard mask 50 as a mask and a silicon oxide film 14 and the silicon substrate 10 are removed selectively. Therefore, the trench 51 is formed.

Furthermore, as shown in FIG. 31, also in the STI region 17 shown in a cross section corresponding to the cross section along the C-C′ line of FIG. 12, the silicon nitride film is formed on the silicon substrate 10 as a film serving as the hard mask 50, and then the hard mask 50 is formed by patterning using the photolithography method or the like.

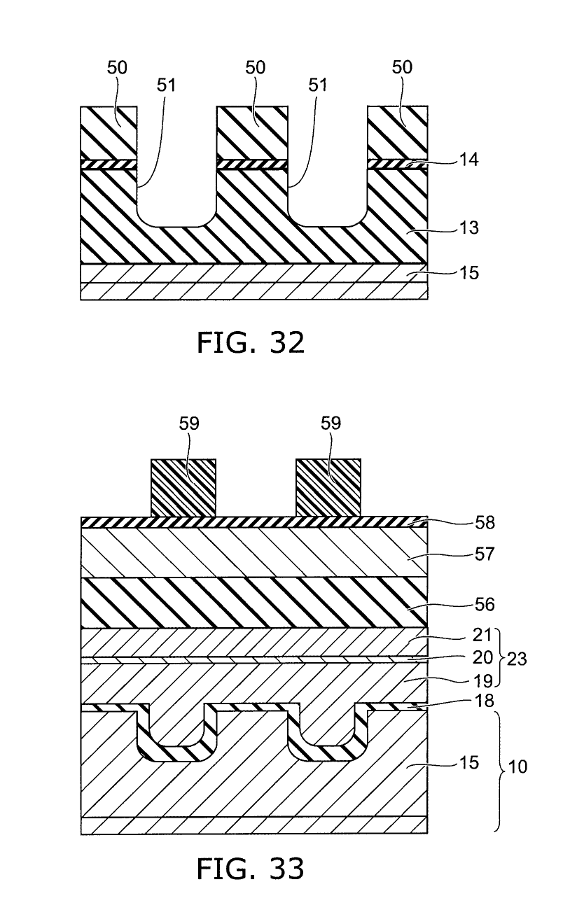

Next, as shown in FIG. 32, a silicon oxide film 13 and the silicon oxide film 14 are removed selectively by reactive ion etching using the hard mask 50 as a mask. Therefore, the trench 51 is formed.

In this manner, the inside of the trench 51 in the active region along the B-B′ line shown in FIG. 12 and the inside of the trench 51 in the STI region along the C-C′ line shown in FIG. 12 have the same structure. Accordingly, only the process cross-sectional view in the active region 16 will be shown in the following.

Next, as shown in FIG. 33, the hard mask 50 and the silicon oxide film 14 are removed on the silicon substrate 10 (refer to FIGS. 29 to 32), and a silicon oxide film 18 serving as the gate insulating layer is formed on the inner surface of the trench 51 and on the upper face of the silicon substrate 10. Next, a poly-silicon film 19 is formed on the silicon oxide film 18 serving as a part of the gate electrode 23. Phosphorus is introduced into this poly-silicon film 19 as an impurity. The poly-silicon film 19 is formed so as to be embedded in the trench 51.

After that, a stacked layer of titanium and titanium nitride, for example, is stacked on the poly-silicon film 19 as the barrier metal film 20. Then, a tungsten (W) film, for example, is formed thereon as the low-resistance metal film 21. In the embodiment, the gate electrode 23 includes the poly-silicon film 19, the barrier metal film 20, and the low-resistance metal film 21. Titanium nitride other than the stacked layer of titanium and titanium nitride can be used as a material of the barrier metal film 20.

Then, a silicon nitride film 56 and an organic film 57 are formed on the low-resistance metal film 21, and then a silicon oxide film 58 is formed thereon. Furthermore, a resist 59 is formed on the silicon oxide film 58. At this time, a formation region of the resist 59 is caused to coincide with the region directly on the trench 51.

Next, the silicon oxide film 58 is patterned by the use of the resist 59 as a mask.

After that, the organic film 57 and the silicon nitride film 56 are processed through the use of the patterned silicon oxide film 58 as a mask.

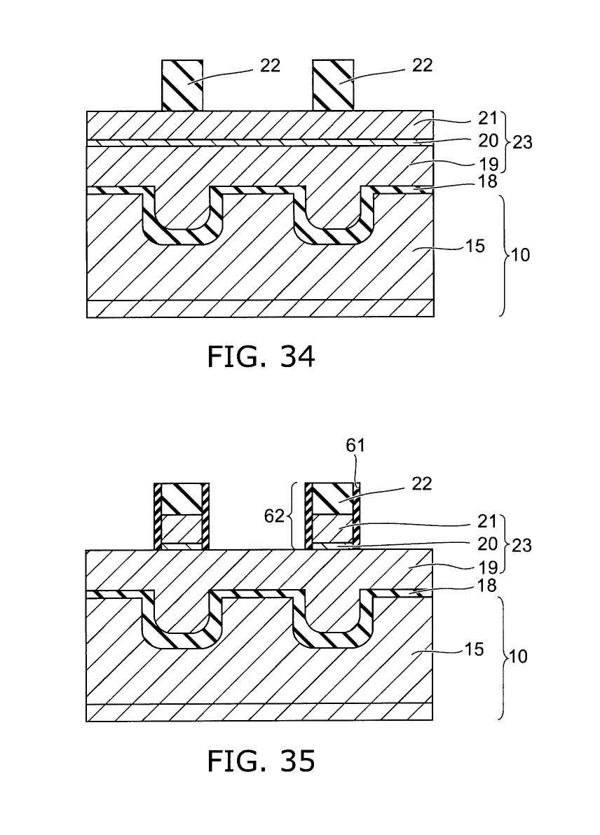

Next, as shown in FIG. 34, in the embodiment, the silicon oxide film 58 and the organic film 57 are removed and the patterned silicon nitride film 56 is set as the hard mask 22.

Next, as shown in FIG. 35, reactive ion etching is carried out through the use of the hard mask 22 as a mask and the low-resistance metal film 21 and the barrier metal film 20 are removed selectively. Therefore, the part of the gate electrode 23 made up of the low-resistance metal film 21 and the barrier metal film 20 is formed in the part covered by the hard mask 22.

Meanwhile, the poly-silicon film 19 appears on the surface of the part which is not covered by the hard mask 22.

When the stacked layer of titanium nitride and titanium is used as the barrier metal film 20, there is a possibility that the titanium is oxidized in post-oxidation after processing the gate electrode.

Accordingly, the barrier metal side wall 61 is formed on a side face of the multilayer film including the hard mask 22, the low-resistance metal film 21, and the barrier metal film 20. A material of the barrier metal side wall 61 can include, for example, a silicon nitride film. The silicon nitride film is formed by a CVD method (Chemical Vapor Deposition) or the like and then is removed in the part except the side face of the multilayer film including the hard mask 22, the low-resistance metal film 21, and the barrier metal film 20 to thereby form the barrier metal side wall 61.

When the barrier metal side wall 61 is formed, the multilayer film including the barrier metal side wall 61, the hard mask 22, the low-resistance metal film 21, and the barrier metal film 20 is referred to as the pillar body 62. When the barrier metal side wall 61 is not formed, the multilayer film including the hard mask 22, the low-resistance metal film 21, and the barrier metal film 20 is referred to as the pillar body 62.

Next, processing of the poly-silicon film 19 is carried out. In the embodiment, the gate electrode 23 is configured to have a three-layered structure of the poly-silicon film 19, the barrier metal film 20, and the low-resistance metal film 21. Accordingly, the poly-silicon film 19 is the lowermost layer film of the gate electrode 23.

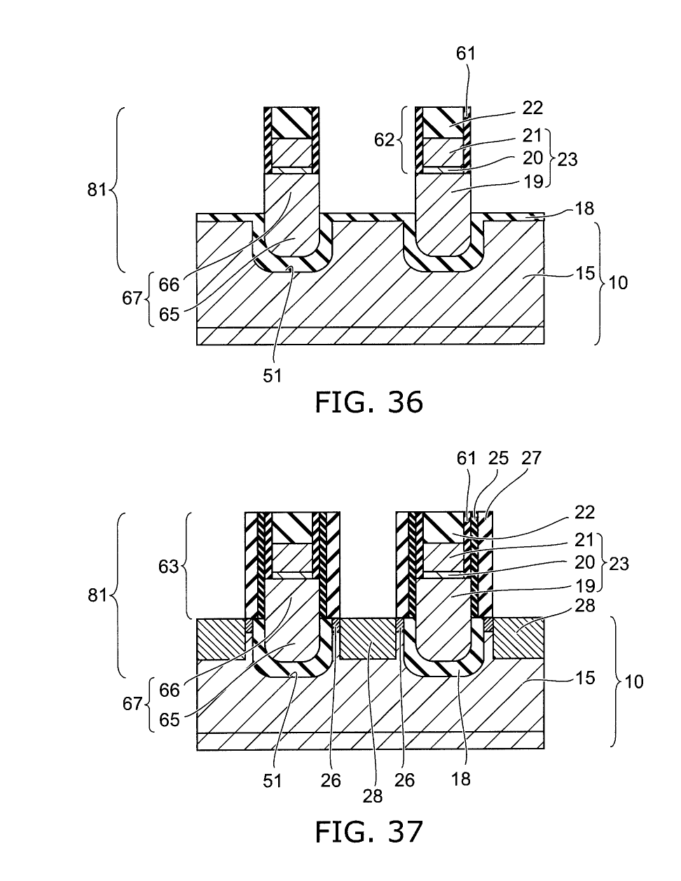

Next, as shown in FIG. 36, the poly-silicon film 19 in the part thereof formed between the gate electrodes 23 is removed. When the poly-silicon film 19 in the part thereof between the gate electrodes 23 is removed, the silicon oxide film 18 appears on the surface.

After that, as shown in FIG. 37, the silicon oxide film 18 on the silicon substrate 10 between the gate electrodes 23, that is, the silicon oxide film 18 except the silicon oxide film 18 on the inner surface of the trench 51 which provides the gate insulating layer, is removed. The silicon oxide film 18 remains within the trench 51.

The stacked layer including the pillar body 62 and the upper conduction part 66 is referred to as the pillar body 63. Furthermore, the stacked layer including the pillar body 63, the lower conduction part 65, and the silicon oxide film 18 is referred to as the stacked bodies 81.

Then, the extension side wall 25 is formed on the side face of the pillar body 63 in the stacked bodies 81. Next, phosphorus is ion-implanted in the silicon substrate 10 through the use of the pillar body 63 and the extension side wall 25 as a mask to thereby form the extended region 26.

Furthermore, the source-drain side wall 27 is formed on the side face of the pillar body 63 in the stacked bodies 81. Then, phosphorus is ion-implanted in the silicon substrate 10 through the use of the pillar body 63, the extension side wall 25, and the source-drain side wall 27 as a mask to thereby form the source-drain region 28.

Next, the processes shown in FIGS. 19 to 22 of the fourth embodiment are carried out and the stopper film 29 and the insulating side wall 31 are formed. Also in the embodiment, the upper end side face of the gate electrode 23 is covered by the insulating side wall 31 and the side face of the gate electrode 23 in the part thereof contacting the gate insulating layer is not covered by the insulating side wall 31.

Furthermore, the processes shown in FIGS. 23 to 24 of the fourth embodiment are carried out and the interlayer insulating layer 33 and the multilayer resist film are formed on the silicon substrate 10.

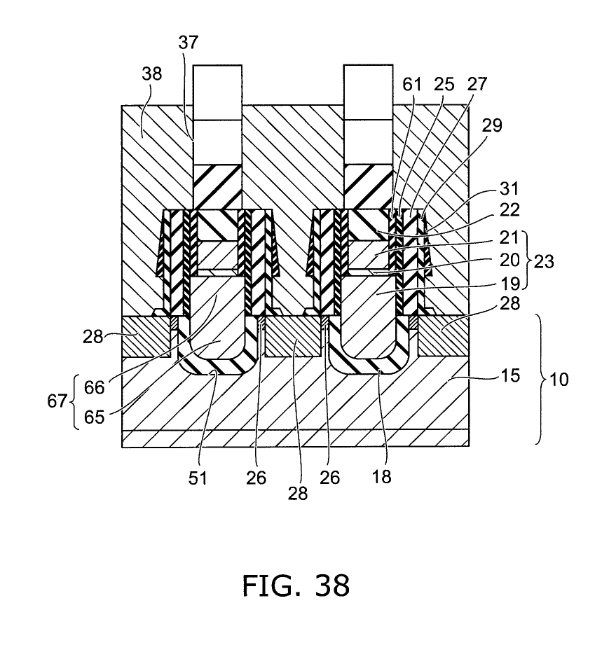

Then, as shown in FIG. 38, a self-aligned contact hole 37 is formed and the contact 38 is provided.

In this manner, as shown in FIGS. 3 and 4, the semiconductor device 2 is manufactured.

Next, an advantage of the manufacturing method of a semiconductor device according to the fifth embodiment will be described.

A transistor having the recess structure can be realized and it is possible to provide a semiconductor device which can realize a higher integration.

The advantage of the embodiment except the above is the same as that of the fourth embodiment, and thus explanation will be omitted.

### Sixth Embodiment

Next, a manufacturing method of a semiconductor device according to a sixth embodiment will be described.

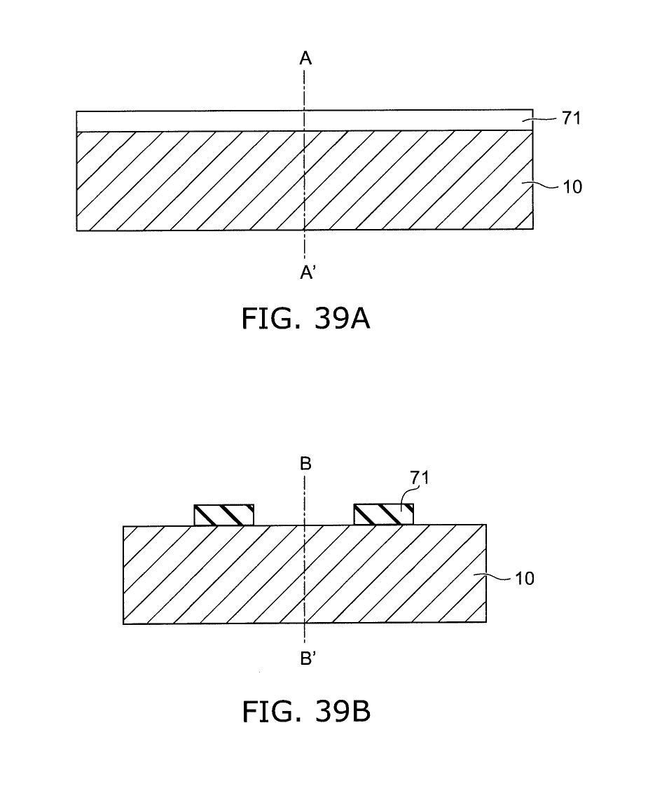

FIGS. 39A and 39B to 44A and 44B are process cross-sectional views illustrating the manufacturing method of a semiconductor device according to the sixth embodiment, and A is a process cross-sectional view along the B-B′ line shown in B and B is a process cross-sectional view along the A-A′ line shown in A, in each of the drawings.

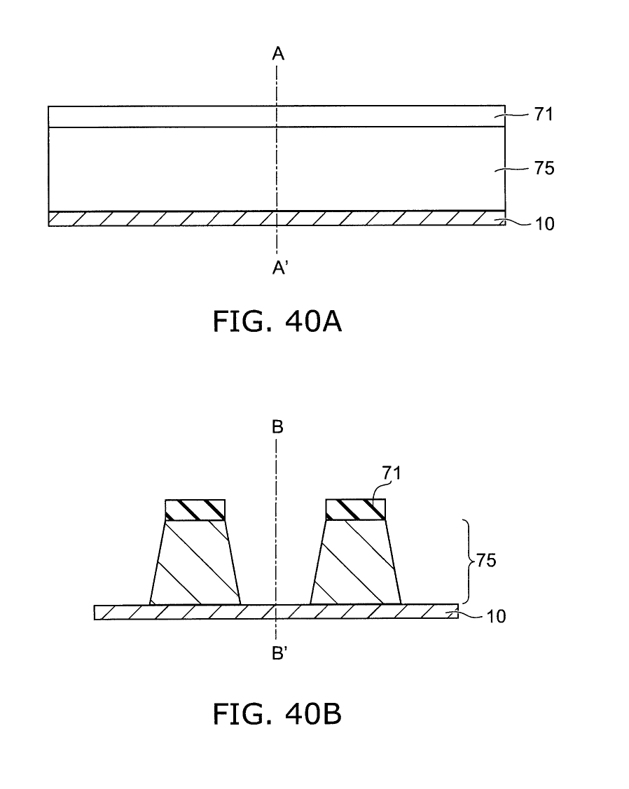

First, as shown in FIGS. 39A and 39B, a silicon substrate 10 made up of single crystal silicon (Si), for example, is prepared. After that, a silicon nitride film, for example, is formed, as a film serving as a hard mask 71, on the silicon substrate 10, and then the hard mask 71 is formed by patterning using the photography method or the like. The hard masks 71 are formed in parallel to one another in one direction on the silicon substrate 10. Then, as shown in FIGS. 40A and 40B, reactive ion etching is carried out through the use of the hard mask 71 as a mask and the upper layer part of the silicon substrate 10 is removed selectively.

The part covered by the hard mask 71 becomes the pillar body 75. The pillar bodies 75 are formed in parallel to one another in one direction on the silicon substrate 10 as the hard masks 71. The pillar body 75 is integrated with the silicon substrate 10 and has a shape protruding from the silicon substrate 10. The direction perpendicular to the extension direction of the pillar body 75 is referred to as “width” and each of the two faces facing each other in the width direction of the pillar body 75 is referred to as a “side face”. The width of the lower part of the pillar body 75 is formed larger than that of the upper part.

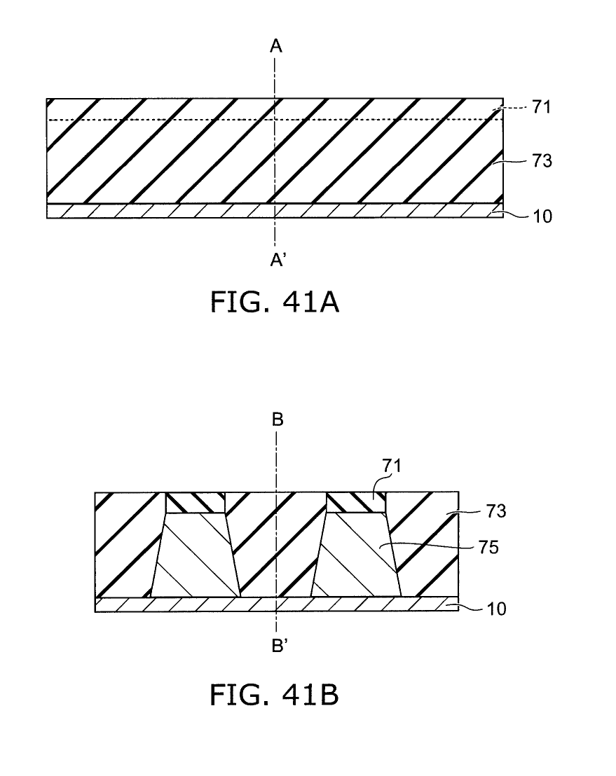

Next, as shown in FIGS. 41A and 41B, the upper face of the silicon substrate 10 including the pillar body 75 covered by the hard mask 71 is covered by the silicon oxide film 73. Then, the silicon oxide film 73 is polished by the CMP method until the surface of the hard mask 71 appears and the upper face of the silicon oxide film 73 is flattened.

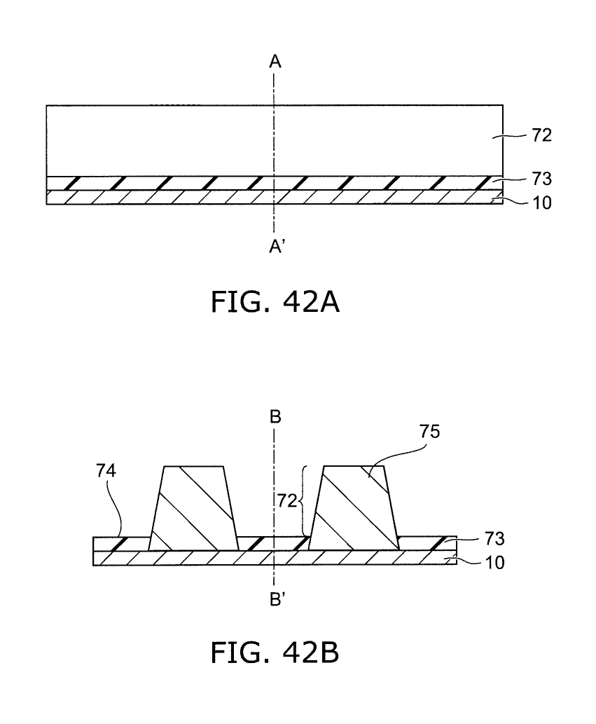

Next, as shown in FIGS. 42A and 42B, the silicon oxide film 73 is caused to be recede downward by dry etching through the use of the hard mask 71 (refer to FIGS. 41A and 41B) as a mask. Then, the hard mask 71 is removed. The region having the remaining silicon oxide film 73 is set as the STI region 74. The part of the pillar body 75 above the silicon oxide film 73 is referred to as the fin 72. Accordingly, the fin 72 is formed on the silicon substrate 10 also so as to extend in one direction. Furthermore, the direction perpendicular to the extension direction of the fin 72 is referred to as “width” and each of the surfaces facing each other in the width direction is referred to as a “side face”.

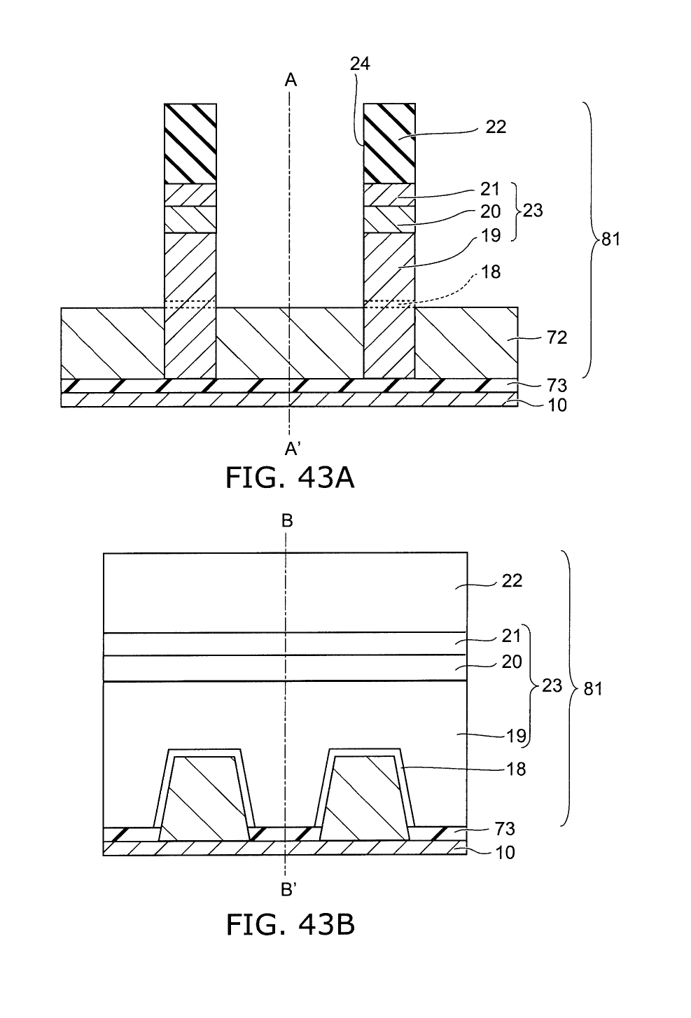

Next, as shown in FIGS. 43A and 43B, the silicon oxide film 18, for example, is formed on the upper face and the side faces of the fin 72 as the gate insulating layer.

After that, the poly-silicon film 19 is formed on the silicon oxide film 18 serving as a part of the gate electrode 23. The poly-silicon film 19 is formed at a height larger than the fin 72 so as to cover the fin 72.

Then, a tungsten nitride film, for example, is formed on the poly-silicon film 19 as the barrier metal film 20. Then, a tungsten film, for example, is formed thereon as the low-resistance metal film 21. In the embodiment, the gate electrode 23 includes the poly-silicon film 19, the barrier metal film 20, and the low-resistance metal film 21.

The hard mask 22 is formed on the low-resistance metal film 21. A silicon nitride film, for example, is formed on the low-resistance metal film 21 and then the hard mask 22 is formed by patterning through the use of the lithography method. The hard mask 22 is formed so as to perpendicularly cross the direction of the fin 72.

Next, reactive ion etching is carried out through the use of the hard mask 22 as a mask, and the low-resistance metal film 21, the barrier metal film 20, the poly-silicon film 19, and the silicon oxide film 18 are removed selectively. Therefore, the gate electrode 23 including the low-resistance metal film 21, the barrier metal film 20, and the poly-silicon film 19 is formed in the part covered by the hard mask 22.

In contrast, the upper face and the side faces of the fin 72 appear on the surface of the part which is not covered by the hard mask 22.

Furthermore, the stacked bodies 81 including the hard mask 22, the gate electrode 23, and the silicon oxide film 18 is formed as a pillar body extending in the direction perpendicular to the extension direction of the fin 72 and the STI region 74. The trench 24 is formed between the neighboring stacked bodies 81. That is, the formed trench 24 divides the stacked bodies 81. The trench 24 extends in the same direction as the extension direction of the stacked bodies 81.

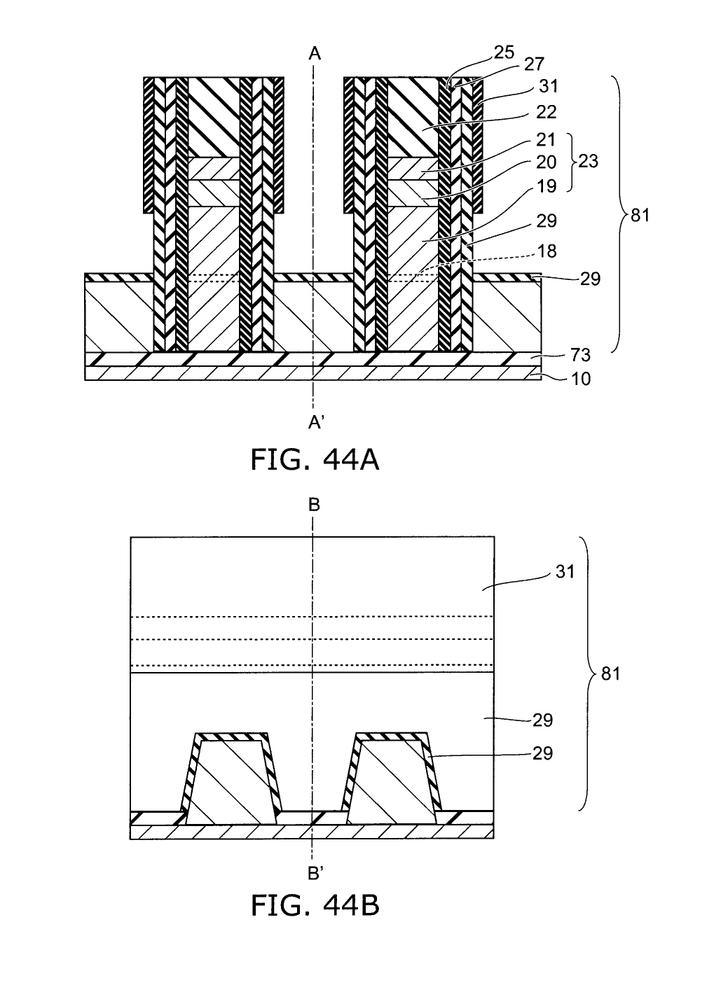

Next, as shown in FIGS. 44A and 44B, the processes in FIGS. 19 to 22 of the fourth embodiment are carried out, and the extension side wall 25, the source-drain side wall 27, the stopper film 29, and the insulating side wall 31 are formed on the side face of the stacked bodies 81. The extension side wall 25, the source-drain side wall 27, and the stopper film 29 are formed on the upper face and the side faces of the fin 72 so as to cross over the fin 72.

Furthermore, also in the embodiment, the upper end part side face of the gate electrode is covered by the insulating side wall 31 and the side face of the gate electrode 23 in the part thereof contacting the gate insulating layer is not covered by the insulating side wall 31.

Then, the processes in FIGS. 23 to 24 of the fourth embodiment are carried out and the interlayer insulating layer 33 and the multilayer resist film are formed. Then, a self-aligned contact hole 37 is formed and a contact 38 is formed.

In this manner, as shown in FIGS. 5 and 6, the semiconductor device 3 is manufactured.

According to the above described embodiments, it is possible to provide a semiconductor device and a manufacturing method thereof which are capable of realizing a higher integration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a semiconductor substrate;
plural stacked bodies which are provided on the semiconductor substrate so as to extend in parallel to one another and each of the plural stacked bodies includes
a gate insulating layer provided on the semiconductor substrate,
a gate electrode provided on the gate insulating layer, and
an insulating layer provided on the gate electrode;
an insulating side wall which covers a side face of the gate electrode in an upper end part thereof and does not cover the side face of the gate electrode in a part thereof contacting the gate insulating layer;
an interlayer insulating layer which is provided on the semiconductor substrate and covers the stacked bodies; and
a contact which is provided in the interlayer insulating layer between the stacked bodies and is connected to the semiconductor substrate.

2. The device according to claim 1, wherein
a part of the contact which is not sandwiched by the insulating side walls has a larger width than a part of the contact which is sandwiched by the insulating side walls.

3. The device according to claim 1, wherein
plural trenches are formed on an upper face of the semiconductor substrate so as to extend in an extension direction of the stacked bodies,
the gate insulating layer is provided on an inner surface of the trench, and
a part of the gate electrode is embedded within the trench.

4. The device according to claim 1, wherein
plural fins are formed on an upper face of the semiconductor substrate so as to extend in a direction intersecting with an extension direction of the stacked bodies, and
the gate insulating layer is provided on an upper face and side faces of the fin.

5. The device according to claim 1, wherein
the gate electrode includes
a poly-silicon film, and
a metal film provided on the poly-silicon film.

6. The device according to claim 1, wherein
the interlayer insulating layer includes silicon oxide.

7. The device according to claim 1, further comprising:
an extension side wall provided on a side face of the stacked bodies;
a source-drain side wall provided on a side face of the extension side wall;
a stopper film provided on a side face of the source-drain side wall and on a part of the semiconductor substrate, the part being located between respective regions directly below the stacked bodies;
an extension region which is formed on the semiconductor substrate in a region directly below the source-drain side wall and in which impurities have been introduced; and
a source-drain region which is formed on the semiconductor substrate in a part between the respective regions directly below the stacked bodies and between the extension regions and has an impurity concentration higher than that of the extension region.

8. The device according to claim 7, wherein
the extension side wall, the source-drain side wall, the stopper film, the insulating side wall, and the hard mask include the same material.

9. The device according to claim 8, wherein
the material includes silicon nitride.

10. A manufacturing method of a semiconductor device, comprising:
forming an insulating layer on a semiconductor substrate;
forming a conductive film on the insulating layer;
forming plural hard masks on the conductive film, the plural hard masks having an insulating property and extending in parallel to one another;
stacking the insulating layer, the conductive film, and the hard mask to thereby form plural stacked bodies which extend in parallel to one another, by etching the conductive film and the insulating layer through the use of the hard mask as a mask;
embedding sacrificial material in a part which is located in a lower part of a space between the stacked bodies and includes at least a space between the insulating layers, but does not include a space between the hard masks;
forming an insulating side wall on a side face of the stacked bodies on the sacrificial material;
removing the sacrificial material;
forming an interlayer insulating layer on the semiconductor substrate, the interlayer insulating layer covering the stacked bodies;
forming a through-hole in the interlayer insulating layer, the through-hole reaching the semiconductor substrate; and
embedding conductive material in the through-hole and forming a contact.

11. The method according to claim 10, wherein
the sacrificial material includes carbon.

12. The method according to claim 10, wherein
the embedding sacrificial material includes
forming a film including carbon on the semiconductor substrate by a chemical vapor deposition method using gas including carbon, nitrogen, and hydrogen, and
removing the film in a part thereof located between respective upper ends of the conductive films and thereabove.

13. The method according to claim 10, wherein
the embedding sacrificial material includes
forming a film including carbon on the semiconductor substrate by a sputter method, and
removing the film in a part thereof located between respective upper ends of the conductive films and thereabove.

14. The method according to claim 10, wherein
the embedding sacrificial material includes
forming a film including carbon on the semiconductor substrate by a spin-coating method, and
removing the film in a part thereof located between respective upper ends of the conductive films and thereabove.

15. The method according to claim 10, further comprising
forming plural trenches on the semiconductor substrate, the plural trenches extending in an extension direction of the stacked bodies, wherein
the insulating layer is also formed on an inner surface of the trench in the forming an insulating layer,
the conductive film is formed so as to be embedded in the trench in the forming a conductive film, and
the hard mask is formed so as to cover a part of a region directly above the trench in the forming a hard mask.

16. The method according to claim 10, further comprising
forming plural fins on the semiconductor substrate, the plural fins extending in a direction intersecting with an extension direction of the stacked bodies, wherein
the insulating layer is formed also on side faces and an upper face of the fin in the forming an insulating layer.

17. The method according to claim 10, wherein
the forming a conductive film includes
forming a poly-silicon film on the insulating layer, and
forming a metal film on the poly-silicon film.

18. The method according to claim 10, wherein
the interlayer insulating layer is formed by material including silicon oxide.

19. The method according to claim 10, further comprising:
forming an extension side wall on a side face of the stacked bodies;
forming an extension region by implanting impurities through the use of the stacked bodies and the extension side wall as a mask;
forming a source-drain side wall on a side face of the extension side wall;
forming a source-drain region by implanting impurities through the use of the stacked bodies, the extension side wall, and the source-drain side wall as a mask, the source-drain region having a higher impurity concentration than that of the extension region; and
forming a stopper film on a side face of the source-drain side wall and on the source-drain region before the forming an insulating side wall, wherein
the extension side wall, the source-drain side wall, the stopper film, the insulating side wall, and the hard mask are formed so as to include the same material.

20. The method according to claim 19, wherein
the material includes silicon nitride.
